(19) United States
(12) Patent Application Publication
(10) Pub. No.: US 2023/0154936 A1
(43) Pub. Date: May 18, 2023

(54) DISPLAY DEVICE AND MANUFACTURING METHOD OF DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventors: Likun Cheng, Wuhan (CN); Liang Sun, Wuhan (CN); Shijuan Yi, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 17/285,901

(22) PCT Filed: Jan. 29, 2021
(86) PCT No.: PCT/CN2021/074341

§ 371 Date: Apr. 15, 2021

(30) Foreign Application Priority Data
Jan. 13, 2021 (CN) 202110041393.0

(51) Int. Cl. H01L 27/12

(52) U.S. Cl. CPC H01L 27/1244; H01L 27/1288

(57) ABSTRACT

The present invention discloses a display device and a manufacturing method of the display device. The display device includes a plurality of pixel island regions separated from each other and a plurality of connecting hinge regions connecting adjacent pixel island regions to each other. The display device further includes a first metal layer. The first metal layer is patterned to form an anode in each of the pixel island regions and is patterned to form at least one metal trace in each of the connecting hinge regions.

### FIELD OF INVENTION

The present invention is related to the field of display technology, and specifically, to a display device and a manufacturing method of the display device.

### BACKGROUND OF INVENTION

Compared to foldable and rollable display screens, stretchable flexible display screens have characteristics of lightness, thinness, low power consumption, and adjustable mechanical properties. The stretchable flexible display screens can be stretched in any direction and still retain a good display effect. It is one of key directions of next generation of new flexible display research.

In current display devices, in order to facilitate tensile strain, flexible polyimide (PI) substrates are dispersed in island shapes, and these polyimide islands are connected by ribbon-shaped connecting hinge regions. Pixel circuits are distributed on the polyimide islands, and metal traces between the pixel circuits are distributed on the ribbon-shaped hinge regions.

When the display devices are stretched and deformed, the connecting hinge regions are deformed by force, and strain resistances of the connecting hinge regions are inversely proportional to their widths. Currently, metal layers in the pixel island regions usually use titanium-molybdenum-titanium (Ti/Mo/Ti) laminated composite structures to form gates, sources, drains, gate lines, source lines, and drain lines. Due to a poor bending resistance of the metal layers containing molybdenum, the metal layers are not suitable for forming metal traces in the connecting hinge regions. Meanwhile, the metal traces are usually parallelly distributed in a same layer in the connecting hinge regions and a certain distance is reserved amongst them in a horizontal direction to prevent short circuits. This causes the connecting hinge regions to be too wide and affects a bending performance of the connecting hinge regions.

In summary, the connecting hinge regions in the prior art have technical problems that their widths are too large, their bending resistances are poor, and they are prone to fracture and failure during a stretching process, thereby affecting normal display of the display devices.

### SUMMARY OF INVENTION

The present invention provides a display device and a manufacturing method of the display device to reduce widths of connecting hinge regions, enhance bending resistances of the connecting hinge regions, and reduce risks of fracture and failure of the connecting hinge regions during a stretching process.

In order to solve the above problems, in a first aspect, the present invention provides a display device including:

a plurality of pixel island regions separated from each other; and

a plurality of connecting hinge regions connecting adjacent pixel island regions to each other.

The display device further includes a first metal layer. The first metal layer is patterned to form an anode in each of the pixel island regions and is patterned to form at least one metal trace in each of the connecting hinge regions.

In an embodiment of the present invention, the display device further includes a second metal layer and a third metal layer disposed in different layers. The second metal layer is patterned to form a first source/drain in each of the pixel island regions. The third metal layer is patterned to form a second source/drain in each of the pixel island regions.

In an embodiment of the present invention, the second metal layer and the third metal layer are respectively patterned to form at least one metal trace in each of the connecting hinge regions.

In an embodiment of the present invention, the display device further includes a thin-film transistor array layer, a first planarization layer, a second planarization layer, and a third planarization layer stacked in sequence. The thin-film transistor array layer is defined with an opening in at least one of the connecting hinge regions. The opening is filled with an organic filling layer. Materials of the organic filling layer, the first planarization layer, the second planarization layer, and the third planarization layer are insulating materials. The second metal layer is disposed between the organic filling layer and the first planarization layer. The third metal layer is disposed between the first planarization layer and the second planarization layer. The first metal layer is disposed between the second planarization layer and the third planarization layer.

In an embodiment of the present invention, a structure of the first metal layer, the second metal layer, and the third metal layer is a titanium-aluminum-titanium laminated composite structure.

In an embodiment of the present invention, the at least one metal trace includes part or all of a first driving power line, a second driving power line, a reset signal line, a first scan line, a second scan line, a light-emitting control signal line, and data lines.

In an embodiment of the present invention, a third metal layer is patterned to form the first driving power line and the second driving power line in each of the connecting hinge regions. The reset signal line, the first scan line, the second scan line, the light-emitting control signal line, and the data lines are formed in the first metal layer or the second metal layer.

In an embodiment of the present invention, each of the pixel island regions includes a plurality of subpixels including at least one red subpixel, at least one green subpixel, and at least one blue subpixel.

In a second aspect, the present invention provides a manufacturing method of a display device. The manufacturing method is configured to manufacture any one of the display devices in the first aspect and includes steps of:

providing a base substrate including a pixel island region and a connecting hinge region and forming a thin-film transistor array layer on the base substrate;

forming an interlayer dielectric layer on the thin-film transistor array layer, forming a second metal layer on the interlayer dielectric layer, and forming a first planarization layer on the second metal layer;

forming a third metal layer on the first planarization layer and forming a second planarization layer on the third metal layer;

forming a first metal layer on the second planarization layer and forming an anode and a metal trace by etching and patterning the first metal layer through a same photomask process; and

forming a third planarization layer on the first metal layer.

In an embodiment of the present invention, the step of forming the anode and the metal trace by etching and patterning the first metal layer further includes: forming a patterned first photoresist on the first metal layer through a first photomask process; and

etching the first metal layer not covered by the first photoresist to form the patterned anode and the metal trace in a same layer as the anode.

In an embodiment of the present invention, the manufacturing method further includes: forming a patterned first source/drain and a metal trace in a same layer as the first source/drain through a second photomask process after the step of forming the second metal layer; and

forming a patterned second source/drain and a metal trace in a same layer as the second source/drain after the step of forming the third metal layer.

In an embodiment of the present invention, the step of forming the thin-film transistor array layer further includes: forming a fourth metal layer on the base substrate and forming a patterned first gate by etching the fourth metal layer through a fourth photomask process; and

a step of forming a second gate: forming a fifth metal layer on the first gate and forming the patterned second gate by etching the fifth metal layer through a fifth photomask process.

In an embodiment of the present invention, the manufacturing method further includes forming a deep hole in a portion of the interlayer dielectric layer positioned in the connecting hinge region through a sixth photomask process and obtaining an organic filling layer by filling an organic material in the deep hole through a seventh photomask process after the step of forming the interlayer dielectric layer.

In an embodiment of the present invention, the step of forming the thin-film transistor array layer further includes forming a patterned active layer on the base substrate through an eighth photomask process.

In an embodiment of the present invention, the manufacturing method further includes forming the first planarization layer through a ninth photomask process, forming the second planarization layer through a tenth photomask process, and forming the third planarization layer through an eleventh photomask process.

In an embodiment of the present invention, materials of the first metal layer, the second metal layer, and the third metal layer include titanium-aluminum-titanium laminated composite materials.

In an embodiment of the present invention, the obtained metal trace includes part or all of a first driving power line, a second driving power line, a reset signal line, a first scan line, a second scan line, a light-emitting control signal line, and data lines.

In an embodiment of the present invention, the third metal layer is patterned to form the first driving power line and the second driving power line in the connecting hinge region. The reset signal line, the first scan line, the second scan line, the light-emitting control signal line, and the data lines are formed in the first metal layer or the second metal layer.

In an embodiment of the present invention, the pixel island region includes a plurality of subpixels including at least one red subpixel, at least one green subpixel, and at least one blue subpixel.

Compared to a display device and a manufacturing method of the display device in the prior art, the present invention optimizes a structure of the first metal layer. The first metal layer is patterned to form the anode in each of the pixel island regions and is patterned to form at least one metal trace in each of the connecting hinge regions. Because there is no metal trace disposed in a same layer as the anode before this improvement, without increasing a number of photomasks and a number of photomask processes, this optimization can increase a number of film layers forming the metal trace, reduce a number of metal traces in a same film layer, and reduce an overall width of the connecting hinge regions. Therefore, a bending resistance of the connecting hinge regions is enhanced, risks of fracture and failure of the connecting hinge regions during a stretching process are reduced, and a production yield rate and product quality are increased.

### DESCRIPTION OF DRAWINGS

In order to describe technical solutions in the present invention clearly, drawings to be used in the description of embodiments will be described briefly below. Obviously, drawings described below are only for some embodiments of the present invention, and other drawings can be obtained by those skilled in the art based on these drawings without creative efforts.

FIG. 1 is a structural schematic diagram of a display device in the prior art.

FIG. 2 is a structural schematic diagram of a connecting hinge region in the prior art.

FIG. 3 is a top view of a display device of an embodiment of the present invention.

FIG. 4 is a structural schematic diagram of the display device of an embodiment of the present invention.

FIG. 5 is a structural schematic diagram of a connecting hinge region of an embodiment of the present invention.

FIG. 6 is a wiring schematic diagram of a pixel island region of an embodiment of the present invention.

FIG. 7 is a flowchart of a manufacturing method of an embodiment of the present invention.

### DETAILED DESCRIPTION OF PREFERRED EMBODIMENTS

The technical solution of the present invention embodiment will be clarified and completely described with reference accompanying drawings in embodiments of the present invention embodiment. Obviously, the present invention described parts of embodiments instead of all of the embodiments. Based on the embodiments of the present invention, other embodiments which can be obtained by a skilled in the art without creative efforts fall into the protected scope of the of the present invention.

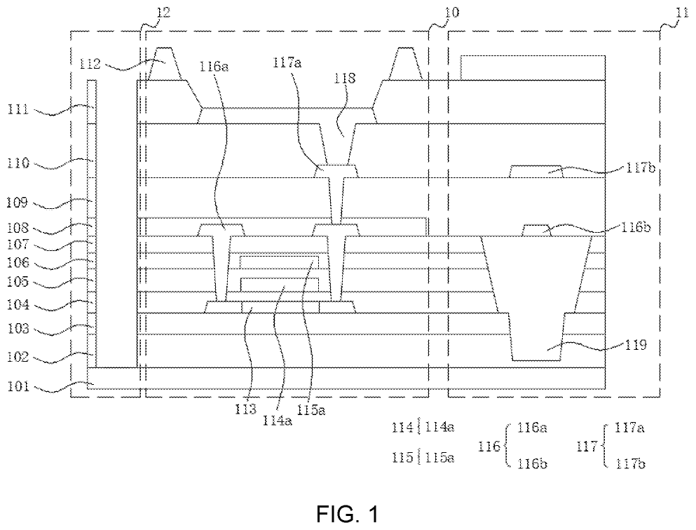

In a current display device, as shown in FIGS. 1 and 2. FIG. 1 is a structural schematic diagram of a display device in the prior art. FIG. 2 is a structural schematic diagram of a connecting hinge region in the prior art. A stretchable display panel includes a pixel island region 20, a connecting hinge region 11, and an opening region 12. The opening region 12 only provided with a glass substrate 101, and no film layer is provided on the glass substrate 101. On the one hand, it can save materials and reduce costs, and on the other hand, it leaves a deformation range for the connecting hinge region 11. The stretchable display panel further includes the glass substrate 101, a polyimide layer 102, a buffer layer 103, a first gate insulating layer 104, a second gate insulating layer 105, a first interlayer dielectric layer 106, a second Interlayer dielectric layer 107, an insulating layer 108, a first planarization layer 109, a second planarization layer 110, a pixel definition layer 111, a spacer 112, an active layer 113, a first gate layer 114, a second gate layer 115, a first source/drain layer 116, a second source/drain layer 117, an anode layer 118, and a first organic filling layer 119. The first gate layer 114 is patterned to form a first gate 114a in the pixel island region 20. The second gate layer 115 is patterned to form a second gate 115a in the pixel island region 20. The first source/drain layer 116 is patterned to form a first source/drain 116a in the pixel island region 20 and is patterned to form a first metal trace layer 116b in the connecting hinge region 11. The second source/drain layer 117 is patterned to form a second source/drain 117a in the pixel island region 20 and is patterned to form a second metal trace layer 117b in the connecting hinge region 11. The first source/drain 116a and the first metal trace layer 116b are arranged in a same layer. The second source/drain 117a and the second metal trace 117b are arranged in a same layer. One or more metal traces are provided in any one of the metal trace layers. When a plurality of the metal traces are provided in a same metal trace layer, the plurality metal traces are parallelly distributed and a certain distance is reserved amongst them in a horizontal direction to prevent short circuits. Especially in the first metal trace layer 116b, there are usually four metal traces, widths of the four metal traces and space between each metal traces cause the connecting hinge region 11 to be too wide and affects a bending performance of the connecting hinge regions.

Based on this, an embodiment of the present invention provides a display device and a manufacturing method of the display device. Detailed descriptions are as follows.

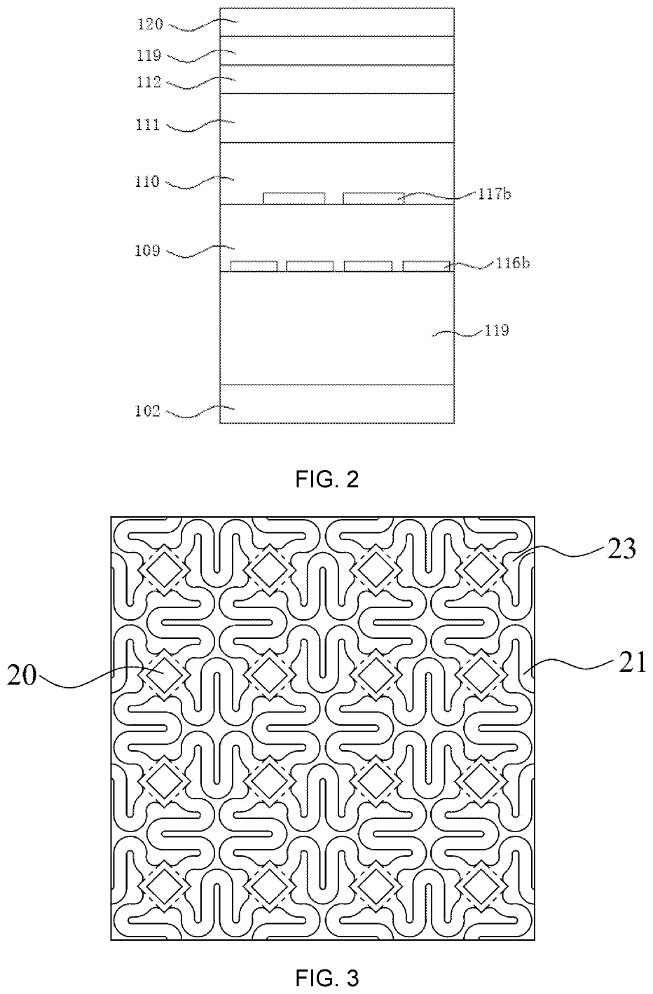

First, an embodiment of the present invention provides a display device as shown in FIG. 3. FIG. 3 is a top view of the display device of an embodiment of the present invention. The display device includes a plurality of pixel island regions 20 separated from each other and a plurality of connecting hinge regions 21. The plurality of connecting hinge regions 21 connect adjacent pixel island regions 20 to each other. The display device further includes a first metal layer 210. The first metal layer 210 is patterned to form an anode 210a in each of the pixel island regions 20 and is patterned to form at least one metal trace 210b in each of the connecting hinge regions 21.

Compared to a display device and a manufacturing method of the display device in the prior art, the present invention optimizes a structure of the first metal layer 210. The first metal layer is patterned to form the anode 210a in each of the pixel island regions 20 and is patterned to form at least one metal trace 210b in each of the connecting hinge regions 21. Because there is no metal trace 210b disposed in a same layer as the anode 210a before this improvement, without increasing a number of photomasks and a number of photomask processes, this optimization can increase a number of film layers forming the metal trace, reduce a number of metal traces in a same film layer, and reduce an overall width of the connecting hinge regions 21. Therefore, a bending resistance of the connecting hinge regions 21 is enhanced, risks of fracture and failure of the connecting hinge regions 21 during a stretching process are reduced, and a production yield rate and product quality are increased.

In an embodiment of the present invention, the display device includes three types of regions: the pixel island regions 20, the connecting hinge regions 21, and opening regions 22. The connecting hinge regions 21 connect the separated pixel island regions 20. The pixel island regions 20 include thin-film transistors and light-emitting elements. Each of the connecting hinge region 21 includes a bending portion bent in at least two directions. When the display device is stretched, an angle of the bending portion changes, the angle of the bending portion becomes greater during a stretching process, and the angle of the bending portion decreases during a shrinking process. Stresses can be dispersed throughout the connecting hinge regions 21 by changing the angle of the bending portion. Understandably, the display device not only has a certain stretching property, but also has a certain shrinkage property.

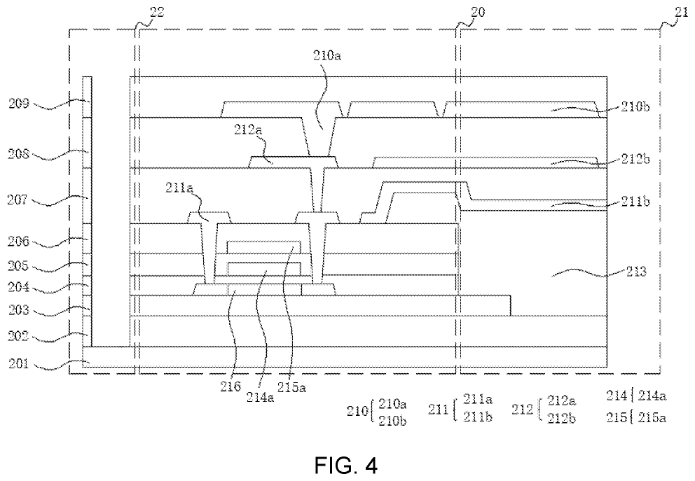

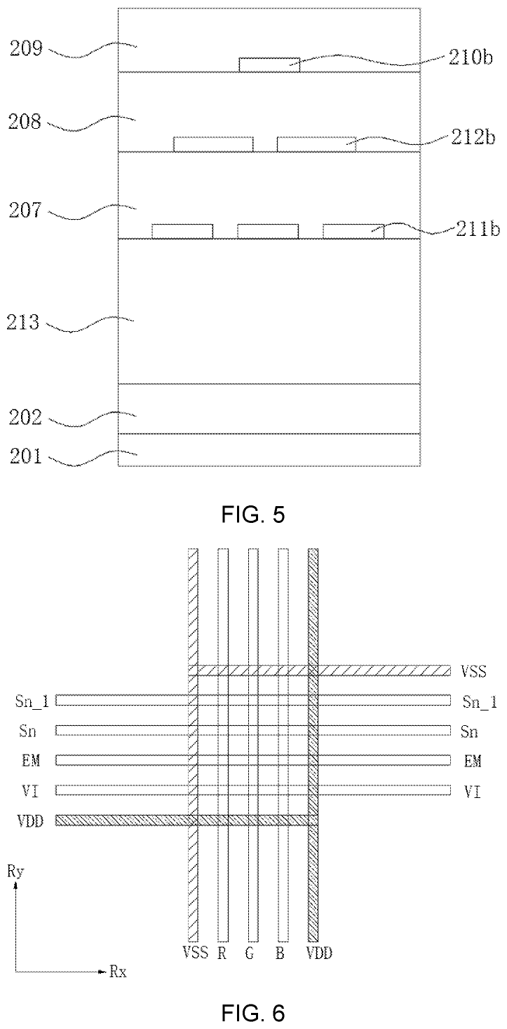

Please refer to FIGS. 4 and 5. FIG. 4 is a structural schematic diagram of the display device of an embodiment of the present invention. FIG. 5 is a structural schematic diagram of a connecting hinge region of an embodiment of the present invention. In a cross-sectional view, the three types of regions of the display device are shown in FIG. 4, and an opening region 22 is shown in a left region in the figure. The opening region 22 is only provided with a base substrate 201, and no film layer is provided on the base substrate 201. On the one hand, it can save materials and reduce costs, and on the other hand, it leaves a deformation range for the connecting hinge region 21 and enhances a bending resistance of the display device. A pixel island region 20 is shown in a middle region in the figure. The connecting hinge region 21 is shown in a right region in the figure. Each pixel island region 20 and connecting hinge region 21 includes a plurality of laminated film layers. At least one of the pixel island regions 20 further includes a second metal layer 211 and a third metal layer 212 disposed in different layers. The second metal layer 211 is patterned to form a first source/drain 211a in each of the pixel island regions 20. The third metal layer 212 is patterned to form a second source/drain 212a in each of the pixel island regions 20.

In an embodiment of the present invention, the connecting hinge region 21 further includes two film layers forming the metal trace, which are the second metal layer 211 and the third metal layer 212 respectively. The second metal layer 211 is patterned to form the first source/drain 211a in each of the pixel island regions 20 and is patterned to form at least one metal trace 211b in each of the connecting hinge regions 21. The third metal layer 212 is patterned to form the second source/drain 212a in each of the pixel island regions 20 and is patterned to form at least one metal trace 212b in each of the connecting hinge regions 21. The above-mentioned metal trace 210b refers to a first metal trace 210b disposed in a same layer as the anode 210a. The above-mentioned metal trace 211 b refers to a second metal trace 211b disposed in a same layer as the first source/drain 211a. The above-mentioned metal trace 212b refers to a third metal trace 212b disposed in a same layer as the second source/drain 212a. Orthographic projections of at least two layers of the first metal trace 210b, the second metal trace 211b, or the third metal trace 212b at least partially overlap. If the orthographic projections of at least two of the three film layers at least partially overlap, a size (i.e., width) of the connecting hinge region 21 in the horizontal direction can be reduced to a certain extent. In an extreme case, the orthographic projections of the three film layers overlap, and a film layer with a greatest width of the three film layers covers the other two film layers, and if other conditions are same, the connecting hinge region 21 has a least width at this time.

In this embodiment, the display device includes a thin-film transistor array layer, a first planarization layer 207, a second planarization layer 208, and a third planarization layer 209 stacked in sequence. The thin-film transistor array layer is defined with an opening in at least one of the connecting hinge regions 21. The opening is filled with an organic filling layer 213. Materials of the organic filling layer 213, the first planarization layer 207, the second planarization layer 208, and the third planarization layer 209 are insulating materials. The second metal layer 211 is disposed between the organic filling layer 213 and the first planarization layer 207. The third metal layer 212 is disposed between the first planarization layer 207 and the second planarization layer 208. The first metal layer 211 is disposed between the second planarization layer 208 and the third planarization layer 209. The connecting hinge region 21 includes a plurality of metal traces. Any two adjacent metal traces are filled with the insulating materials to prevent short circuits between different metal traces. The thin-film transistor array layer includes a first gate insulating layer 204, a second gate insulating layer 205, an interlayer dielectric layer 206, an active layer 216, a first metal layer 214, and a second metal layer 215.

Before the organic filling layer 213 is formed, an opening needs to be defined in the connecting hinge region 21. A cross section of the opening is inverted trapezoidal. The opening is filled with the organic filling layer 213. Most of the first gate insulating layer 204, the second gate insulating layer 205, and the interlayer dielectric layer 206 disposed in a same layer as the organic filling layer 213 in the pixel island region 20 are inorganic film layers, which have a poor bending performance. In this embodiment, disposing the organic filling layer 213 not only has the above-mentioned insulation function, but also can greatly enhance the bending resistance of the connecting hinge region 21.

On a basis of the above embodiment, the pixel island region 20 includes a base substrate 201, a polyimide layer 202, a buffer layer 203, the first gate insulating layer 204, the second gate insulating layer 205, the interlayer dielectric layer 206, the first planarization layer 207, the second planarization layer 208, and the third planarization layer 209 sequentially stacked from bottom to top. It further includes the first metal layer 210, the second metal layer 211, the third metal layer 212, a fourth metal layer 214, a fifth metal layer 215, and an active layer 216. The connecting hinge region 21 includes the thin-film transistor array layer, the second metal layer 211, the first planarization layer 207, the third metal layer 212, the second planarization layer 208, the first metal layer 210, and the third planarization layer 209 sequentially stacked from bottom to top. The fourth metal layer 214 is patterned to form a first gate 214a in the pixel island region 20. The fifth metal layer 215 is patterned to form a second gate 215a in the pixel island region 20. It is worth mentioning that an opening is provided in the thin-film transistor array layer, and the opening is filled with the organic filling layer 213. There is no second gate 215a in an embodiment, only part of film layers of the connecting hinge region 21 is described herein, and another part of film layers is same as film layers of the pixel island region 20, which is not described repeatedly. The first metal trace 210b, the second metal trace 211b, and the third metal trace 212b can be referred by metal trace layers, and the metal trace layers refer to at least one metal trace formed by a corresponding metal layer.

The connecting hinge region 21 includes a plurality of metal traces, and the plurality of metal wires include part or all of a first driving power line VSS, a second driving power line VDD, a reset signal line VI, a first scan line Sn, a second scan line Sn_1, a light-emitting control signal line EM, and data lines (R, G, and B). The third metal layer 212 is patterned to form the first driving power line VSS and the second driving power line VDD in the connecting hinge regions 21. The reset signal line VI, the first scan line Sn, the second scan line Sn_1, the light-emitting control signal line EM, and the data lines (R, G, and B) are formed in the first metal layer 210 or the second metal layer 211. A width of any one of the first driving power line VSS or the second driving power line VDD is greater than or equal to a width of any one of the reset signal line VI, the first scan line Sn, the second scan line Sn_1, the light-emitting control signal line EM, or the data lines (R, G, and B).

The widths of the first driving power line VSS and the second driving power line VDD are greater than or equal to other metal traces. In the prior art, due to a limitation of a manufacturing process, the widths of the first driving power line VSS and the second driving power line VDD are usually relatively large, which are generally greater than other metal traces. Therefore, the first driving power line VSS and the second driving power line VDD are usually disposed in the third metal layer 212, and other metal traces are disposed in the second metal layer 211. Because a number of the metal traces formed by the second metal layer 211 in the prior art is relatively large, which is usually three or more than three metal traces, an overall width of the second metal trace 211b is greater than an overall width of the third metal trace 212b. A width and a spacing of the metal traces in the second metal traces 211b are as small as possible without affecting their own performance and causing short circuits. A width and a spacing of the metal traces in the third metal trace 212b have some margins, which can be expanded or narrowed within an appropriate range. In an embodiment of the present invention, the third metal layer 212 with a smaller number of the metal traces remains unchanged, the metal traces formed by the second metal layer 211 are shunted, and the reset signal line VI, the first scan line Sn, the second scan line Sn_1, the light-emitting control signal line EM, and the data lines (R, G, and B) are formed in the first metal layer 210 or the second metal layer 211. That is, as described in the above embodiment, at least one metal trace in the second metal layer 211 is transferred to the first metal layer 210. The overall width of the second metal trace 211b is reduced accordingly, so that the overall width of the connecting hinge region 21 can be reduced without affecting its own performance and causing short circuits.

In order to prevent the width of the added first metal trace 210b from being too large, the number of the metal traces formed by any one of the second metal layer 211 or the third metal layer 212 is greater than or equal to the number of the metal traces formed by the first metal layer 211. It is worth mentioning that disposing the first driving power line VSS and the second driving power line VDD in the third metal layer 212 is a preferred embodiment. In an actual production, the widths of the first driving power line VSS, the second driving power line VDD, the reset signal line VI, the first scan line Sn, the second scan line Sn_1, the light-emitting control signal line EM, and the data lines (R, G, and B) can be freely adjusted. Therefore, specific positions distributed in the first metal layer 210, the second metal layer 211, or the third metal layer 212 are determined according to requirements.

Please refer to FIG. 6. FIG. 6 is a wiring schematic diagram of the pixel island region of an embodiment of the present invention. The data lines (R, G, and B) include a first data line, a second data line, and a third data line, which respectively input R, G, and B signals. The pixel island region 20 includes the plurality of metal traces interlaced in different directions. As shown in the figure, the first driving power line VSS, the second driving power line VDD, the reset signal line VI, the first scan line Sn, the second scan line Sn_1, and the light-emitting control signal line EM are in a Rx direction. The first driving power line VSS, the second driving power line VDD, the first data line, the second data line, and the third data line are in a Ry direction. Different connecting hinge regions 21 are connected in different directions. Furthermore, the connecting hinge regions 21 connected toward different directions in a same direction are also different; for example, the plurality of metal traces in some connecting hinge regions 21 (e.g., the metal traces toward up and down as shown in the figure) have a same composition, and the plurality of metal traces in other connecting hinge regions 21 (e.g., the metal traces toward left and right as shown in the figure) have different composition. It is worth mentioning that, in an embodiment, the connecting hinge region 21 in the Rx direction includes both the first driving power line VSS and the second driving power line VDD. In another embodiment, the connecting hinge region 21 in the Rx direction includes only one of the first driving power line VSS or the second driving power line VDD. Obviously, the width of the connecting hinge region 21 including only one of the two can be smaller than that of the connecting hinge region 21 including both of the two. Therefore, by reducing the number of the plurality of metal traces in a same connecting hinge region 21, the width of the connecting hinge region 21 can also be reduced.

Usually, only part of the data lines in the pixel island region 20 are included in a same connecting hinge region 21. However, the number and the composition of the plurality of metal traces included in different connecting hinge regions 21 can be same or different. In an embodiment, there are five metal traces included in a same connecting hinge region 21, such as the first driving power line VSS/the second driving power line VDD, the reset signal line VI, the first scan line Sn, the second scan line Sn_1, and the light-emitting control signal line EM, or the first driving power line VSS, the second driving power line VDD, the first data line, the second data line, and the third data line. In another embodiment, there are six metal traces included in a same connecting hinge region 21, such as the first driving power line VSS, the second driving power line VDD, the reset signal line VI, the first scan line Sn, the second scan line Sn_1, and the light-emitting control signal line EM.

Understandably, first, the present invention takes using a same photomask process to form the anode 210a and the metal trace 210b by etching and patterning on the first metal layer 210 as an example. In fact, if there is a further requirement, the metal traces in a same layer as other metal layers can be formed by optimizing or improving other film layers of the metal layers etched by photomasks. It is also possible to increase a number of layers distributed with the metal traces without increasing the number of the photomasks and the number of photomask processes.

Second, the third metal layer 212 in the above embodiment forms two metal traces, the number of the metal traces formed by the second metal layer 211 changes, and the first metal layer 210 forms one metal trace. In fact, the number of the metal traces formed in each metal layer can be changed, and the second metal layer 211 and the third metal layer 212 can form one or not form the metal trace, so the first metal layer can form two or more metal traces. Two opposite ends of the metal trace are respectively connected to different pixel island regions 20, and trace paths do not affect its performance, which is subject to specific requirements in an actual production.

Furthermore, the above embodiments take disposing the first driving power line VSS and the second driving power line VDD in the same layer and moving other the metal traces as an example. In fact, there is no corresponding relationship between different film layers and different metal traces. Any of the metal traces can pass through any preset film layer for accommodating the metal traces. This does not limit a protection scope of the present invention.

At last, in the above embodiments, in the connecting hinge region 20, one side surface (e.g., upper surface and lower surface) of any one of the metal trace layers is provided with a planarization layer or the organic filling layer 213. Materials of the planarization layer and the organic filling layer 213 are insulating materials. The planarization layer includes the first planarization layer 207, the second planarization layer 208, and the third planarization layer 209. The planarization layer and the organic filling layer can keep a proper distance between different metal trace layers, and filling the insulating material can further prevent short circuits between the different metal trace layers. Therefore, in fact, the filling is not necessary. However, compared to performing the filling, the distance between the different metal layers needs to be larger when the filling is not performed, which is not conducive to reducing the width and a thickness of the connecting hinge region 20. A filling material is an insulating material with a certain bending resistance but is not limited to organic or inorganic materials.

A structure of the first metal layer 210, the second metal layer 211, and the third metal layer 212 is a titanium-aluminum-titanium laminated composite structure. A bending resistance of aluminum is better than that of platinum. The first metal layer 210, the second metal layer 211, and the third metal layer 212 preferably form bending-resistant metal traces in the connecting hinge region 20. Material of the metal traces include aluminum. Because aluminum has relatively active chemical properties and low strength, titanium is formed on an upper layer and a lower layer or around aluminum for a protection and a support, and a structure of the metal trace is a titanium-aluminum-titanium laminated composite structure. Therefore, the structure of the first metal layer 210, the second metal layer 211, and the third metal layer 212 is a titanium-aluminum-titanium laminated composite structure. In an embodiment, because the fourth metal layer 214 and the fifth metal layer 215 do not form metal traces in the connecting hinge region 21, materials of the fourth metal layer 214 and the fifth metal layer 215 can include aluminum, molybdenum, or other metal materials.

Each of the pixel island regions 20 includes a plurality of subpixels. The plurality of subpixels include at least one red subpixel, at least one green subpixel, and at least one blue subpixel. Each of the subpixels is electrically connected to the data line, the first scan line Sn, and the second scan line Sn_1. In this embodiment, an area of the blue subpixel is larger than the red subpixel or the green subpixel. Each red subpixel, each green subpixel, and each blue subpixel are respectively connected to the corresponding first data line, the corresponding second data line, and the corresponding third data line. Each of the subpixels is electrically connected to the first scan line Sn and the second scan line Sn_1.

In order to better implement the display device in the embodiments of the present invention, on a basis of the display device, the present invention further provides a manufacturing method of the display device. The manufacturing method of the display device is configured to manufacture the display device described in the above embodiment.

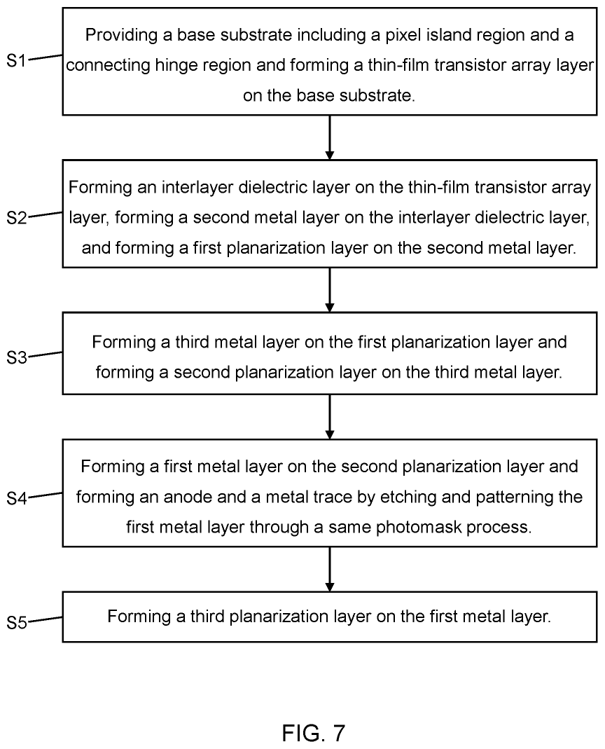

Please refer to FIG. 7. FIG. 7 is a flowchart of a manufacturing method of an embodiment of the present invention. The manufacturing method of the display device includes steps of:

S1, providing a base substrate 201 including a pixel island region 20 and a connecting hinge region 21 and forming a thin-film transistor array layer on the base substrate 201;

S2, forming an interlayer dielectric layer 206 on the thin-film transistor array layer, forming a second metal layer 211 on the interlayer dielectric layer 206, and forming a first planarization layer 207 on the second metal layer 211;

S3, forming a third metal layer 212 on the first planarization layer 207 and forming a second planarization layer 208 on the third metal layer 212;

S4, forming a first metal layer 210 on the second planarization layer 208 and forming an anode 210a and a metal trace 210b by etching and patterning the first metal layer 210 through a same photomask process; and

S5, forming a third planarization layer 209 on the first metal layer 210.

Step S4 of forming the anode 210a and the metal trace 210b by etching and patterning the first metal layer 210 further includes: forming a patterned first photoresist on the first metal layer 210 through a first photomask process; and etching the first metal layer 210 not covered by the first photoresist to form the patterned anode 210a and the metal trace 210b in a same layer as the anode 210a.

Specifically, the first photoresist is formed on the first metal layer 210. The patterned first photoresist is obtained by exposing and developing the first photoresist using the first photomask process. The patterned anode 210a and the metal trace 210b in the same layer as the anode 210a are obtained by etching the first metal layer 210 not covered by the first photoresist and followed by stripping the first photoresist.

The manufacturing method further includes forming a patterned first source/drain 211a and a metal trace 211b in a same layer as the first source/drain 211a through a second photomask process after step S2 of forming the second metal layer. Specifically, the second photoresist is formed on the second metal layer 211. The patterned first source/drain 211a and the metal trace 211b in the same layer as the first source/drain 211a are obtained by patterning the second photoresist through a second photomask process.

The manufacturing method further includes forming a second source/drain 212a and a metal trace 212b in a same layer as the second source/drain 212a after step S3 of forming the third metal layer 212. The third photoresist is formed on the third metal layer 212. The second source/drain 212a and the metal trace 212b in the same layer as the second source/drain 212a are obtained by patterning the third photoresist through a third photomask process.

Step S1 of forming the thin-film transistor array layer further includes: forming a fourth metal layer 214 on the base substrate 201 and forming a patterned first gate 214a by etching the fourth metal layer 214 through a fourth photomask process.

In an embodiment, step S1 further includes a step of forming a second gate 215a: forming a fifth metal layer 515 on the first gate 214a and forming the patterned second gate 215a by etching the fifth metal layer 215 through a fifth photomask process.

The manufacturing method further includes forming a deep hole in a portion of the interlayer dielectric layer 206 positioned in the connecting hinge region 21 through a sixth photomask process and obtaining an organic filling layer 213 by filling an organic material in the deep hole through a seventh photomask process after step S2 of forming the interlayer dielectric layer 206.

On a basis of the above embodiments, the manufacturing method further includes forming an active layer 216 through an eighth photomask process, forming the first planarization layer 207 through a ninth photomask process, forming the second planarization layer 208 through a tenth photomask process, and forming the third planarization layer 209 through an eleventh photomask process. Referring to a structure shown in the figure, a total of eleven photomask processes are adopted in this embodiment. It is worth mentioning that the first photomask process, the second photomask process . . . , and the eleventh photomask process described herein are not arranged in an order of manufacturing but only for a convenience of the description. In an actual production, a manufacturing sequence should be: forming the active layer 216 through the eighth photomask process, forming the first gate 214a through the fourth photomask process, forming the second gate 215a through the fifth photomask process, forming the deep hole through the sixth photomask process, forming the organic filling layer 213 through the seventh photomask process, patterning the second metal layer 211 through the second photomask process, forming the first planarization layer 207 through the ninth photomask process, patterning the third metal layer 212 through the third photomask process, forming the second planarization layer 208 through the tenth photomask process, patterning the first metal layer 210 through the first photomask process, and forming the third planarization layer 209 through the eleventh mask process.

Compared to the prior art, without increasing a number of photomasks and a number of photomask processes, this embodiment patterns the first metal layer 210 in the connecting hinge region 21 to form the metal trace 210b, thereby increasing a number of film layers forming the metal trace, reducing a number of metal traces in a same film layer, and reducing an overall width of the connecting hinge regions. Therefore, a bending resistance of the connecting hinge regions is enhanced, risks of fracture and failure of the connecting hinge regions during a stretching process are reduced, and a production yield rate and product quality are increased. This also saves photomasks and simplifies processes of the manufacturing method.

In the above embodiments, the descriptions of the various embodiments are different in emphases, for contents not described in detail, please refer to related description of other embodiments. In an actual implement, each of the above units or structures can be implemented as independent entities or can be combined arbitrarily and implemented as same one entity or several entities. For specific implementations of the above units, structures or operations, please refer to previous method embodiments, which are not repeated herein.

The present invention is described in detail above, the specific examples of this document are used to explain principles and embodiments of the present invention, and the description of embodiments above is only for helping to understand the present invention. Meanwhile, those skilled in the art will be able to change the specific embodiments and the scope of the present invention according to the idea of the present invention. In the above, the content of the specification should not be construed as limiting the present invention. Above all, the content of the specification should not be the limitation of the present invention.

What is claimed is:

1. A display device, comprising:
a plurality of pixel island regions separated from each other; and
a plurality of connecting hinge regions connecting adjacent pixel island regions to each other;
wherein the display device further comprises a first metal layer, the first metal layer is patterned to form an anode in each of the pixel island regions and is patterned to form at least one metal trace in each of the connecting hinge regions.

2. The display device according to claim 1, further comprising a second metal layer and a third metal layer disposed in different layers;
wherein the second metal layer is patterned to form a first source/drain in each of the pixel island regions, and the third metal layer is patterned to form a second source/drain in each of the pixel island regions.

3. The display device according to claim 2, wherein the second metal layer and the third metal layer are respectively patterned to form at least one metal trace in each of the connecting hinge regions.

4. The display device according to claim 3, further comprising a thin-film transistor array layer, a first planarization layer, a second planarization layer, and a third planarization layer stacked in sequence;
wherein the thin-film transistor array layer is defined with an opening in at least one of the connecting hinge regions, and the opening is filled with an organic filling layer;
wherein materials of the organic filling layer, the first planarization layer, the second planarization layer, and the third planarization layer are insulating materials; and
wherein the second metal layer is disposed between the organic filling layer and the first planarization layer, the third metal layer is disposed between the first planarization layer and the second planarization layer, and the first metal layer is disposed between the second planarization layer and the third planarization layer.

5. The display device according to claim 3, wherein a structure of the first metal layer, the second metal layer, and the third metal layer is a titanium-aluminum-titanium laminated composite structure.

6. The display device according to claim 1, wherein the at least one metal trace comprises part or all of a first driving power line, a second driving power line, a reset signal line, a first scan line, a second scan line, a light-emitting control signal line, and data lines.

7. The display device according to claim 6, wherein a third metal layer is patterned to form the first driving power line and the second driving power line in each of the connecting hinge regions; and
the reset signal line, the first scan line, the second scan line, the light-emitting control signal line, and the data lines are formed in the first metal layer or a second metal layer.

8. The display device according to claim 1, wherein each of the pixel island regions comprises a plurality of subpixels comprising at least one red subpixel, at least one green subpixel, and at least one blue subpixel.

9. A manufacturing method of a display device, comprising steps of:
providing a base substrate comprising a pixel island region and a connecting hinge region and forming a thin-film transistor array layer on the base substrate;
forming an interlayer dielectric layer on the thin-film transistor array layer, forming a second metal layer on the interlayer dielectric layer, and forming a first planarization layer on the second metal layer;
forming a third metal layer on the first planarization layer and forming a second planarization layer on the third metal layer;
forming a first metal layer on the second planarization layer and forming an anode and a metal trace by etching and patterning the first metal layer through a same photomask process; and
forming a third planarization layer on the first metal layer.

10. The manufacturing method according to claim 9, wherein the step of forming the anode and the metal trace by etching and patterning the first metal layer further comprises:
forming a patterned first photoresist on the first metal layer through a first photomask process; and
etching the first metal layer not covered by the first photoresist to form the patterned anode and the metal trace in a same layer as the anode.

11. The manufacturing method according to claim 9, further comprising:
forming a patterned first source/drain and a metal trace in a same layer as the first source/drain through a second photomask process after the step of forming the second metal layer; and
forming a patterned second source/drain and a metal trace in a same layer as the second source/drain after the step of forming the third metal layer.

12. The manufacturing method according to claim 9, wherein the step of forming the thin-film transistor array layer further comprises:
forming a fourth metal layer on the base substrate and forming a patterned first gate by etching the fourth metal layer through a fourth photomask process; and
forming a fifth metal layer on the first gate and forming a patterned second gate by etching the fifth metal layer through a fifth photomask process.

13. The manufacturing method according to claim 9, further comprising forming a deep hole in a portion of the interlayer dielectric layer positioned in the connecting hinge region through a sixth photomask process and obtaining an organic filling layer by filling an organic material in the deep hole through a seventh photomask process after the step of forming the interlayer dielectric layer.

14. The manufacturing method according to claim 9, wherein the step of forming the thin-film transistor array layer further comprises forming a patterned active layer on the base substrate through an eighth photomask process.

15. The manufacturing method according to claim 9, further comprising forming the first planarization layer through a ninth photomask process, forming the second planarization layer through a tenth photomask process, and forming the third planarization layer through an eleventh photomask process.

16. The manufacturing method according to claim 9, wherein materials of the first metal layer, the second metal layer, and the third metal layer comprise titanium-aluminum-titanium laminated composite materials.

17. The manufacturing method according to claim 9, wherein the obtained metal trace comprises part or all of a first driving power line, a second driving power line, a reset signal line, a first scan line, a second scan line, a light-emitting control signal line, and data lines.

18. The manufacturing method according to claim 17, wherein the third metal layer is patterned to form the first driving power line and the second driving power line in the connecting hinge region; and
the reset signal line, the first scan line, the second scan line, the light-emitting control signal line, and the data lines are formed in the first metal layer or the second metal layer.

19. The manufacturing method according to claim 9, wherein the pixel island region comprises a plurality of subpixels comprising at least one red subpixel, at least one green subpixel, and at least one blue subpixel.
